(19) United States
(12) Patent Application Publication
(10) Pub. No.: US 2021/0321513 A1
(43) Pub. Date: Oct. 14, 2021

(54) ELECTRONIC ASSEMBLY AND METHOD FOR PREPARING THE SAME, AND ELECTRONIC EQUIPMENT

(71) Applicant: Shenzhen Royole Technologies Co., Ltd., Shenzhen (CN)

(72) Inventor: Xiaohua Lei, Shenzhen (CN)

(21) Appl. No.: 17/224,272

(22) Filed: Apr. 7, 2021

(30) Foreign Application Priority Data
Apr. 8, 2020 (CN) 202010282879.9

(51) Int. Cl. H05K 1/02; H05K 1/11

(52) U.S. Cl. CPC H05K 1/0293; H05K 1/115; H05K 1/0283

(57) ABSTRACT

An electronic assembly includes an elastic substrate, a stretchable conductor layer, an electronic element and a compressible elastic conductor. The stretchable conductor layer is arranged on the elastic substrate, the electronic element is located on one side of the stretchable conductor layer facing away from the elastic substrate, and the stretchable conductor layer is electrically connected to the electronic element. The compressible elastic conductor is at least partially located between the stretchable conductor layer and the electronic element.

### CROSS-REFERENCE TO RELATED APPLICATIONS

This application is based upon and claims priority to Chinese Patent Application No. 202010282879.9, filed with the Chinese Patent Office on Apr. 8, 2020, titled “ELECTRONIC ASSEMBLY AND METHOD FOR PREPARING THE SAME, AND ELECTRONIC EQUIPMENT”, the entire contents of which are incorporated herein by reference.

### TECHNICAL FIELD

The present application belongs to the technical field of electronic products and particularly relates to an electronic assembly and a method for preparing the same, and an electronic equipment.

### BACKGROUND

With the continuous development of electronic equipment, the electronic equipment is now popular among users due to its portability and rich and diverse operability. But at the same time, the user [symbol] expectation and demand for the electronic equipment are also higher and higher. For example, the substrate on which the stretchable conductor layer is arranged in current electronic equipment, particularly flexible electronic equipment, is typically an elastic substrate such that the substrate and the stretchable conductor layer can be stretched or bent, etc. In addition, a plurality of electronic elements are usually arranged on the stretchable conductor layer such that the electrical signal transmitted by other components is conducted through the stretchable conductor layer into the electronic elements.

### SUMMARY

A first aspect of the present application provides an electronic assembly, including an elastic substrate, a stretchable conductor layer, an electronic element and a compressible elastic conductor, wherein the stretchable conductor layer is arranged on the elastic substrate, the electronic element is located on one side of the stretchable conductor layer facing away from the elastic substrate, the stretchable conductor layer is electrically connected to the electronic element, and the compressible elastic conductor is at least partially located between the stretchable conductor layer and the electronic element.

A second aspect of the present application provides electronic equipment including the electronic assembly provided by the first aspect of the present application.

A third aspect of the present application provides a method for preparing an electronic assembly, including:

providing an elastic substrate;

forming a stretchable conductor layer covering the elastic substrate;

forming a compressible elastic conductor on the surface of the stretchable conductor layer facing away from the elastic substrate; and

forming an electronic element electrically connected to the stretchable conductor layer on one side of the stretchable conductor layer facing away from the elastic substrate such that the compressible elastic conductor is at least partially located between the stretchable conductor layer and the electronic element.

### BRIEF DESCRIPTION OF THE DRAWINGS

In order to more clearly illustrate the technical schemes in the embodiments of the present application, the drawings used in the embodiments of the present application will be illustrated below, in which like numerals are employed to designate like parts throughout the same.

FIG. 1 is a schematic cross-sectional view of an electronic assembly in an embodiment of the present application.

FIG. 2 is a schematic cross-sectional view of an electronic assembly in another embodiment of the present application.

FIG. 3 is a schematic cross-sectional view of an electronic assembly in yet another embodiment of the present application.

FIG. 4 is a schematic cross-sectional view of an electronic assembly in yet another embodiment of the present application.

FIG. 5 is a schematic cross-sectional view of an electronic assembly in yet another embodiment of the present application.

FIG. 6 is a schematic cross-sectional view of an electronic assembly in yet another embodiment of the present application.

FIG. 7 is a schematic cross-sectional view of an electronic assembly in yet another embodiment of the present application.

FIG. 8 is a schematic cross-sectional view of an electronic assembly in yet another embodiment of the present application.

FIG. 9 is a schematic cross-sectional view of an electronic assembly in yet another embodiment of the present application.

FIG. 10 is a schematic cross-sectional view of an electronic assembly in yet another embodiment of the present application.

FIG. 11 is a schematic cross-sectional view of an electronic assembly in yet another embodiment of the present application.

FIG. 12 is a schematic cross-sectional view of an electronic assembly in yet another embodiment of the present application.

FIG. 13 is a schematic diagram of an electronic equipment in an embodiment of the present disclosure.

FIG. 14 is a process flow diagram of a method for preparing an electronic assembly provided by an embodiment of the present application.

FIGS. 15 to 18 are schematic diagrams showing structures corresponding to S100, S200, S300 and S400 in FIG. 14, respectively.

FIG. 19 is a partial process flow diagram of a method for preparing an electronic assembly provided by another embodiment of the present application.

FIG. 20 is a partial process flow diagram of a method for preparing an electronic assembly provided by yet another embodiment of the present application.

FIG. 21 is a partial process flow diagram of a method for preparing an electronic assembly provided by yet another embodiment of the present application.

FIG. 22 is a partial process flow diagram of a method for preparing an electronic assembly provided by yet another embodiment of the present application.

FIGS. 23 to 25 are schematic diagrams showing structures corresponding to S421, S422 and S423 in FIG. 22, respectively.

FIG. 26 is a partial process flow diagram of a method for preparing an electronic assembly provided by yet another embodiment of the present application.

FIGS. 27 to 28 are schematic diagrams showing structures corresponding to S310 and S320 in FIG. 26, respectively.

FIG. 29 is a partial process flow diagram of a method for preparing an electronic assembly provided by yet another embodiment of the present application.

FIGS. 30 to 31 are schematic diagrams showing structures corresponding to S330 and S340 in FIG. 29, respectively.

FIG. 32 is a partial process flow diagram of a method for preparing an electronic assembly provided by yet another embodiment of the present application.

FIGS. 33 to 36 are schematic diagrams showing structures corresponding to S424, S425, S426 and S427 in FIG. 32, respectively.

FIG. 37 is a partial process flow diagram of a method for preparing an electronic assembly provided by yet another embodiment of the present application.

FIG. 38 is a partial process flow diagram of a method for preparing an electronic assembly provided by yet another embodiment of the present application.

FIGS. 39 to 41 are schematic diagrams showing structures corresponding to S431, S432 and S433 in FIG. 38, respectively.

FIG. 42 is a partial process flow diagram of a method for preparing an electronic assembly provided by yet another embodiment of the present application.

FIGS. 43 to 44 are schematic diagrams showing structures corresponding to S350 and S360 in FIG. 42, respectively.

FIG. 45 is a partial process flow diagram of a method for preparing an electronic assembly provided by yet another embodiment of the present application.

FIGS. 46 to 49 are schematic diagrams showing structures corresponding to S434, S435, S436 and S437 in FIG. 45, respectively.

FIG. 50 is a partial process flow diagram of a method for preparing an electronic assembly provided by yet another embodiment of the present application.

The markings indicate:

an electronic assembly—1, an elastic substrate—10, a stretchable conductor layer—20, an electronic element—30, a compressible elastic conductor—40, a first encapsulating layer—50, a second encapsulating layer—60, an adhesive layer—70, a through-hole—31, a first receiving groove—81, a second receiving groove—82, a third receiving groove—83, a fourth receiving groove—84, a fifth receiving groove—85, a first accommodating hole—91 and a second accommodating hole—92, an electronic equipment—100.

### DETAILED DESCRIPTION

While the following are preferred embodiments of the present application, it should be noted that several improvements and adaptations may be made by one of ordinary skills in the art without departing from the principles of the present application and are to be considered in the scope of the present application.

Before introducing the technical scheme of the present application, the technical problems in the related art are described in detail.

In the related art, electronic equipment, particularly flexible electronic equipment, needs to be provided with an elastic substrate and a stretchable conductor layer such that the substrate and the stretchable conductor layer can be stretched or bent, etc. In addition, a plurality of electronic elements are usually arranged on the stretchable conductor layer such that the electrical signal transmitted by other components is conducted through the stretchable conductor layer into the electronic elements. In the process of stretching or bending or when the ambient environment changes, the substrate and the stretchable conductor layer may stretch. However, during stretching or bending, the contact performance between the electronic element and the stretchable conductor layer can be influenced such that the conductivity of the electronic element can be reduced and even the conductive connection can be disabled.

For example, during stretching, the substrate and the stretchable conductor layer not only increase in length in the horizontal direction, but also decrease in height. However, as the electronic element is made of a rigid material, when the height of the substrate and the stretchable conductor layer is reduced, the height of the electronic element is not reduced. Therefore, microcracks are generated between the electronic element and the stretchable conductor layer such that the contact area between the electronic element and the stretchable conductor layer is changed, and the contact resistance between the electronic element and the stretchable conductor layer is changed, the conductivity of the electronic element is finally reduced, and the conductive connection may even fail.

In view of this, the present application provides an electronic assembly, in which a compressible elastic conductor is additionally arranged between a stretchable conductor layer and an electronic element, and the connection performance between the electronic element and the stretchable conductor layer is improved by using the compression-resilience characteristic of the compressible elastic conductor, thereby improving the conductivity of the electronic element.

Reference is made to FIG. 1, which is a schematic cross-sectional view of an electronic assembly in an embodiment of the present application. The embodiment provides an electronic assembly 1 including an elastic substrate 10, a stretchable conductor layer 20 arranged on the elastic substrate 10, an electronic element 30 located on one side of the stretchable conductor layer 20 facing away from the elastic substrate 10, and a compressible elastic conductor 40. The stretchable conductor layer 20 is electrically connected to the electronic element 30. The compressible elastic conductor 40 is at least partially located between the stretchable conductor layer 20 and the electronic element 30.

The elastic substrate 10 provided by the present application is a substrate having elasticity, i.e., a substrate that can be elastically deformed, such as stretched, bent, folded, etc. Alternatively, the material of the elastic substrate 10 includes organic silica gel or an elastomeric thermoplastic polyurethane (TPU). The stretchable conductor layer 20 is arranged on the elastic substrate 10, and the stretchable conductor layer 20 may also be elastically deformed, for example, stretched, bent, folded, etc. Alternatively, the stretchable conductor layer 20 may be prepared from elastic conductive ink. The electronic element 30 is arranged on one side of the stretchable conductor layer 20 facing away from the elastic substrate 10, and the stretchable conductor layer 20 is electrically connected to the electronic element 30. The electronic element 30 may be a functional element such as integrated functional electronics such as PCB, etc. The function of the stretchable conductor layer 20 is to transmit the electrical signal sent by other components to the electronic element 30 through the stretchable conductor layer 20.

The present application also includes a compressible elastic conductor 40, wherein the compressible elastic conductor has elastic and compressible properties, i.e., the compressible elastic conductor 40 has a compression-resilience characteristic, and the compressible elastic conductor 40 is in a compressed state. In addition, the compressible elastic conductor 40 has the conductive property that allows electrical signals on the stretchable conductor layer 20 to be transmitted through the compressible elastic conductor 40 to the electronic element 30. Alternatively, the compressible elastic conductor 40 includes at least one of an elastic conductive micro-spring structural body and an elastic conductive foaming body. According to the present application, a compressible elastic conductor 40 is additionally arranged between the stretchable conductor layer 20 and the electronic element 30, wherein the compressible elastic conductor 40 is in a compressed state. Because the compressible elastic conductor 40 has a compression-resilience characteristic, the compressible elastic conductor 40 is subjected to the resilient force imparted by the elastic substrate 10 and the stretchable conductor layer 20. The compressible elastic conductor 40 imparts the resilient force to the electronic element 30, and the electronic element 30 decomposes the resilient force into a force in a direction toward the elastic substrate 10 and the stretchable conductor layer 20, such that the electronic element 30 is more closely connected to the stretchable conductor layer 20 when the elastic substrate 10 is stretched, thereby improving the electrical conductivity performance of the electronic element 30. It can also be understood as that the present application ensures the electrical conductivity performance of the electronic element 30 by utilizing the resilient force of the compressible elastic conductor 40 to compensate for the microcrack created between the electronic element 30 and the stretchable conductor layer 20 when the elastic substrate 10 is stretched.

As described above, according to the electronic assembly 1 provided by the present application, by adding the compressible elastic conductor 40 between the stretchable conductor layer 20 and the electronic element 30, the connection performance between the electronic element 30 and the stretchable conductor layer 20 is improved by using the compression-resilience characteristic of the compressible elastic conductor 40, thereby improving the conductivity of the electronic element 30.

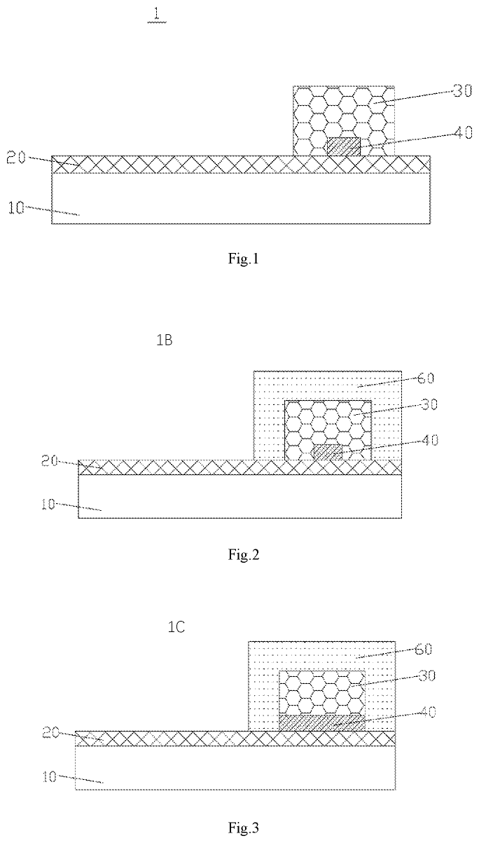

Alternatively, reference is also made to FIG. 2, which is a schematic cross-sectional view of an electronic assembly 1B in another embodiment of the present application. In this embodiment, the electronic assembly 1B further includes a second encapsulating layer 60 on one side of the electronic element 30 remote from the stretchable conductor layer 20, the second encapsulating layer 60 covers the electronic element 30, and the second encapsulating layer 60 partially covers the stretchable conductor layer 20.

According to the present application, the second encapsulating layer 60 can be additionally arranged on one side of the electronic element 30 remote from the stretchable conductor layer 20, so that the second encapsulating layer 60 is connected with the stretchable conductor layer 20, the second encapsulating layer 60 covers the electronic element 30, and the second encapsulating layer 60 partially covers the stretchable conductor layer 20. According to the present application, the second encapsulating layer 60 can be used for enabling the resilient force generated by the compressible elastic conductor 40 to be given to the electronic element 30 and enabling the electronic element 30 to be subjected to a force towards the direction of the stretchable conductor layer 20, such that the electronic element 30 is more closely connected with the stretchable conductor layer 20 when the elastic substrate 10 is stretched, and the conductivity performance of the electronic element 30 is further improved. Alternatively, the electronic assembly 1 further includes a second encapsulating layer 60, which is subsequently illustrated herein.

With regard to the various positional relationships between the compressible elastic conductor 40 and the electronic element 30 and the stretchable conductor layer 20, several kinds of typical positional relationships will be described hereinafter.

Reference is also made to FIG. 3, which is a schematic cross-sectional view of an electronic assembly 1C in yet another embodiment of the present application. In this embodiment, the compressible elastic conductor 40 is located on a surface of the stretchable conductor layer 20 facing away from the elastic substrate 10, and the electronic element 30 is located on a surface of the compressible elastic conductor 40 facing away from the stretchable conductor layer 20, the electronic element 30 being spaced apart from the stretchable conductor layer 20. According to the present application, it is possible to space the electronic element 30 from the stretchable conductor layer 20 by the compressible elastic conductor 40, thereby further improving the size and coverage area of the resilient force and thus further improving the connection performance of the electronic element 30.

Referring again to FIG. 2, in this embodiment, the compressible elastic conductor 40 is located on a surface of the stretchable conductor layer 20 facing away from the elastic substrate 10, and the electronic element 30 covers the compressible elastic conductor 40 and a portion of stretchable conductor layer 20.

According to the present application, it is also possible that the compressible elastic conductor 40 is arranged on a surface of the stretchable conductor layer 20 facing away from the elastic substrate 10, with the electronic element 30 covering the compressible elastic conductor 40 and a portion of stretchable conductor layer 20. It can also be understood that the compressible elastic conductor 40 is embedded into the electronic element 30.

Reference is also made to FIG. 4, which is a schematic cross-sectional view of an electronic assembly 1D in yet another embodiment of the present application. In this embodiment, the surface of the stretchable conductor layer 20 facing the electronic element 30 has a first receiving groove 81, the surface of the electronic element 30 facing the stretchable conductor layer 20 has a second receiving groove 82, the compressible elastic conductor 40 is partially located in the first receiving groove 81, the compressible elastic conductor 40 is partially located in the second receiving groove 82, and the electronic element 30 covers a portion of the stretchable conductor layer 20.

According to the present application, it is also possible that a first receiving groove 81 is formed in the surface of the stretchable conductor layer 20 facing the electronic element 30, a second receiving groove 82 is formed in the surface of the electronic element 30 facing the stretchable conductor layer 20, the first receiving groove 81 and the second receiving groove 82 are arranged opposite to each other, and a portion of the compressible elastic conductor 40 is arranged in the first receiving groove 81 and a portion of the compressible elastic conductor 40 is arranged in the second receiving groove 82. It will also be understood as that a portion of the compressible elastic conductor 40 is embedded in the stretchable conductor layer 20 and a portion of the compressible elastic conductor 40 is embedded in the electronic element 30, thereby increasing the height of the compressible elastic conductor 40 and increasing its resiliency, and thus thereby improving the connection performance between the electronic element 30 and the stretchable conductor layer 20.

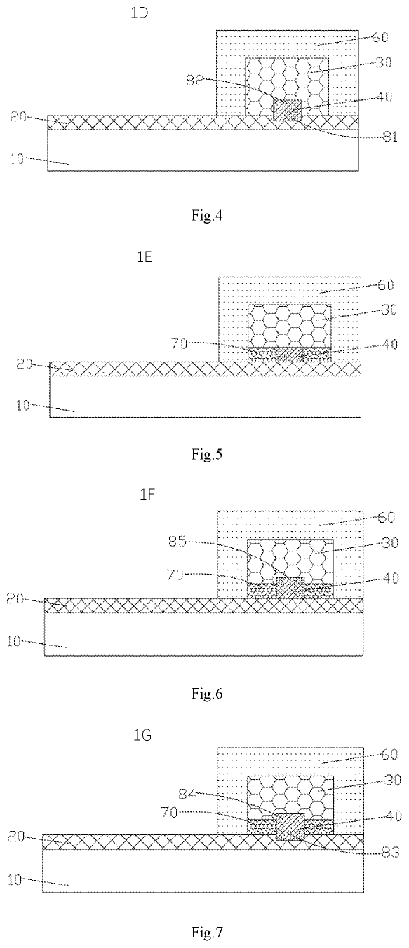

Reference is also made to FIG. 5, which is a schematic cross-sectional view of an electronic assembly 1E in yet another embodiment of the present application. In this embodiment, the compressible elastic conductor 40 is located on a surface of the stretchable conductor layer 20 facing away from the elastic substrate 10, the electronic element 30 is located on a surface of the compressible elastic conductor 40 facing away from the stretchable conductor layer 20, an adhesive layer 70 is arranged between the electronic element 30 and the stretchable conductor layer 20, and the adhesive layer 70 is arranged at least partially around the compressible elastic conductor 40.

According to the present application, the adhesive layer 70 can be arranged on the periphery of the compressible elastic conductor 40 so as to improve the connection performance of the compressible elastic conductor 40, and the adhesive layer 70 can be used for improving the connection performance of the stretchable conductor layer 20 and the electronic element 30 so as to further improve the stability of the electronic assembly 1E. Alternatively, the adhesive layer 70 includes non-conductive glue or conductive glue.

Reference is also made to FIG. 6, which is a schematic cross-sectional view of an electronic assembly 1F in yet another embodiment of the present application. In this embodiment, the surface of the electronic element 30 facing the stretchable conductor layer 20 has a fifth receiving groove 85, the compressible elastic conductor 40 is partially located in the fifth receiving groove 85, an adhesive layer 70 is arranged between the electronic element 30 and the stretchable conductor layer 20, and the adhesive layer 70 is arranged at least partially around the compressible elastic conductor 40.

According to the present application, the adhesive layer 70 can be arranged on the periphery of the compressible elastic conductor 40 so as to improve the connection performance of the compressible elastic conductor 40, and the adhesive layer 70 can be used for improving the connection performance of the stretchable conductor layer 20 and the electronic element 30 so as to further improve the stability of the electronic assembly 1F. In addition, according to the present application, a portion of the compressible elastic conductor 40 can be arranged in the fifth receiving groove 85 formed in the surface of the electronic element 30, thereby improving the height of the compressible elastic conductor 40 and the resilience thereof, and thus improving the connection performance between the electronic element 30 and the stretchable conductor layer 20.

Reference is also made to FIG. 7, which is a schematic cross-sectional view of an electronic assembly 1G in yet another embodiment of the present application. In this embodiment, the surface of the stretchable conductor layer 20 facing the electronic element 30 has a third receiving groove 83, the surface of the electronic element 30 facing the stretchable conductor layer 20 has a fourth receiving groove 84, the compressible elastic conductor 40 is partially located in the third receiving groove 83, and the compressible elastic conductor 40 is partially located in the fourth receiving groove 84. An adhesive layer 70 is arranged between the electronic element 30 and the stretchable conductor layer 20, and the adhesive layer 70 is arranged at least partially around the compressible elastic conductor 40.

According to the present application, the adhesive layer 70 can be arranged on the periphery of the compressible elastic conductor 40 so as to improve the connection performance of the compressible elastic conductor 40, and the adhesive layer 70 can be used for improving the connection performance of the stretchable conductor layer 20 and the electronic element 30 so as to further improve the stability of the electronic assembly 1G. In addition, according to the present application, a portion of the compressible elastic conductor 40 can be arranged in the third receiving groove 83 formed in the surface of the stretchable conductor layer 20, and a portion of the compressible elastic conductor 40 can be arranged in the fourth receiving groove 84 formed in the surface of the electronic element 30, thereby further improving the height of the compressible elastic conductor 40 and the resilience thereof, and thus improving the connection performance between the electronic element 30 and the stretchable conductor layer 20.

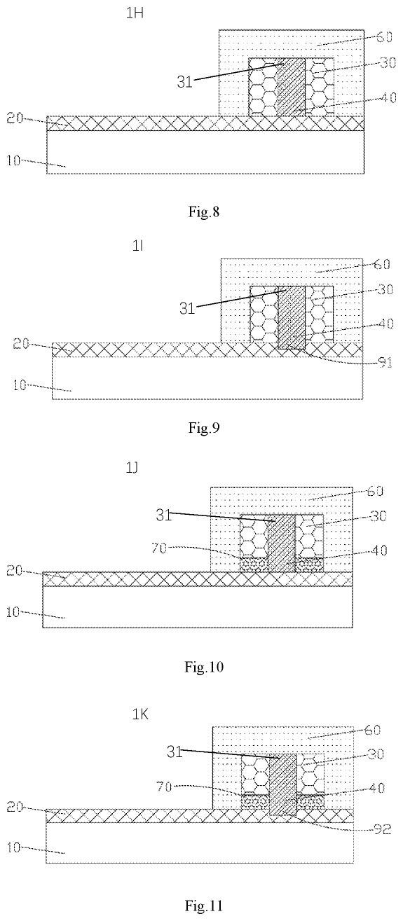

Reference is also made to FIG. 8, which is a schematic cross-sectional view of an electronic assembly 1H in yet another embodiment of the present application. In this embodiment, the electronic element 30 is located on the surface of the stretchable conductor layer 20, and the electronic element 30 has a through-hole 31 in which the compressible elastic conductor 40 is located.

The present application may also arrange a through-hole 31 in the electronic element 30 and arrange the compressible elastic conductor 40 in the through-hole 31. This not only further increases the height of the compressible elastic conductor 40, thereby increasing its resiliency. The resilient force of the compressible elastic conductor 40 may also act directly on the second encapsulating layer 60, thereby increasing the force imparted to the electronic element 30 by the second encapsulating layer 60 and increasing the utilization of the resilient force.

Reference is also made to FIG. 9, which is a schematic cross-sectional view of an electronic assembly 1I in yet another embodiment of the present application. In this embodiment, the electronic element 30 has a through-hole 31, the surface of the stretchable conductor layer 20 facing the electronic element 30 has a first accommodating hole 91, the compressible elastic conductor 40 is partially located in the through-hole 31, and the compressible elastic conductor 40 is partially located in the first accommodating hole 91.

First, the present application may also arrange a through-hole 31 in the electronic element 30 and arrange the compressible elastic conductor 40 in the through-hole 31. This not only further increases the height of the compressible elastic conductor 40, thereby increasing its resiliency. The resilient force of the compressible elastic conductor 40 may also act directly on the second encapsulating layer 60, thereby increasing the force imparted to the electronic element 30 by the second encapsulating layer 60 and increasing the utilization of the resilient force. Secondly, according to the present application, a portion of the compressible elastic conductor 40 can be arranged in the first accommodating hole 91 formed in the stretchable conductor layer 20, such that the height of the compressible elastic conductor 40 is further improved, the resilient force of the compressible elastic conductor 40 is improved, and the connection performance between the electronic element 30 and the stretchable conductor layer 20 is further improved.

Reference is also made to FIG. 10, which is a schematic cross-sectional view of an electronic assembly 1J in yet another embodiment of the present application. In this embodiment, the electronic element 30 is spaced from the stretchable conductor layer 20, the electronic element 30 has a through-hole 31 in which the compressible elastic conductor 40 is partially located, an adhesive layer 70 is arranged between the electronic element 30 and the stretchable conductor layer 20, and the adhesive layer 70 at least partially surrounds the compressible elastic conductor 40.

First, the present application may also arrange a through-hole 31 in the electronic element 30 and arrange the compressible elastic conductor 40 in the through-hole 31. This not only further increases the height of the compressible elastic conductor 40, thereby increasing its resiliency. The resilient force of the compressible elastic conductor 40 may also act directly on the second encapsulating layer 60, thereby increasing the force imparted to the electronic element 30 by the second encapsulating layer 60 and increasing the utilization of the resilient force. Secondly, the present application may further arrange the adhesive layer 70 on the periphery of the compressible elastic conductor 40 to improve the connection performance of the compressible elastic conductor 40, and may further improve the connection performance of the stretchable conductor layer 20 and the electronic element 30 by using the adhesive layer 70 to further improve the stability of the electronic assembly 1J.

Reference is also made to FIG. 11, which is a schematic cross-sectional view of an electronic assembly 1K in yet another embodiment of the present application. In this embodiment, the electronic element 30 is spaced from the stretchable conductor layer 20, the electronic element 30 has a through-hole 31, the surface of the stretchable conductor layer 20 facing the electronic element 30 has a second accommodating hole 92, the compressible elastic conductor 40 is partially located in the through-hole 31, the compressible elastic conductor 40 is partially located in the second accommodating hole 92, an adhesive layer 70 is arranged between the electronic element 30 and the stretchable conductor layer 20, and the adhesive layer 70 at least partially surrounds the compressible elastic conductor 40.

First, the present application may also arrange a through-hole 31 in the electronic element 30 and arrange the compressible elastic conductor 40 in the through-hole 31. This not only further increases the height of the compressible elastic conductor 40, thereby increasing its resiliency. The resilient force of the compressible elastic conductor 40 may also act directly on the second encapsulating layer 60, thereby increasing the force imparted to the electronic element 30 by the second encapsulating layer 60 and increasing the utilization of the resilient force. Secondly, the present application may further arrange the adhesive layer 70 on the periphery of the compressible elastic conductor 40 to improve the connection performance of the compressible elastic conductor 40, and may further improve the connection performance of the stretchable conductor layer 20 and the electronic element 30 by using the adhesive layer 70 to further improve the stability of the electronic assembly 1K. Thirdly, according to the present application, a portion of the compressible elastic conductor 40 can be arranged in a second accommodating hole 92 formed in the stretchable conductor layer 20, such that the height of the compressible elastic conductor 40 is further improved, the resilient force of the compressible elastic conductor 40 is improved, and the connection performance between the electronic element 30 and the stretchable conductor layer 20 is further improved.

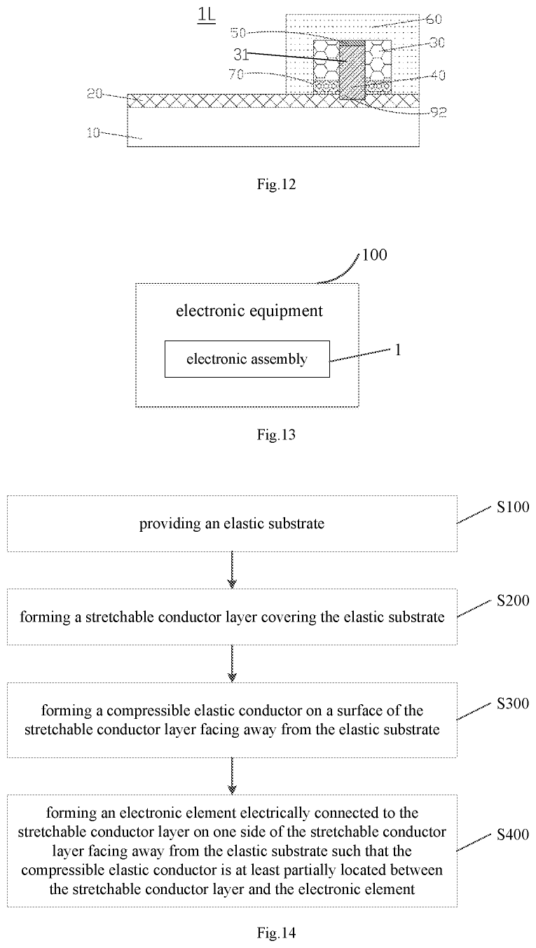

Reference is also made to FIG. 12, which is a schematic cross-sectional view of an electronic assembly 1L in yet another embodiment of the present application. In this embodiment, the electronic assembly 1L further includes a first encapsulating layer 50 located in the through-hole 31 and located on the surface of the compressible elastic conductor 40 remote from the stretchable conductor layer 20.

First, the present application may also arrange a through-hole 31 in the electronic element 30 and arrange the compressible elastic conductor 40 in the through-hole 31. This not only further increases the height of the compressible elastic conductor 40, thereby increasing its resiliency. The resilient force of the compressible elastic conductor 40 may also act directly on the second encapsulating layer 60, thereby increasing the force imparted to the electronic element 30 by the second encapsulating layer 60 and increasing the utilization of the resilient force. Secondly, the present application may further arrange a first encapsulating layer 50 on the surface of the compressible elastic conductor 40 remote from the stretchable conductor layer 20, with one side of the first encapsulating layer 50 connected to the compressible elastic conductor 40, and the other side of the first encapsulating layer 50 connected to a second encapsulating layer to better fix the compressible elastic conductor 40. Alternatively, the first encapsulating layer 50 includes a glue layer or a conductive glue layer or a mechanical member and the like. Alternatively, this embodiment is illustrated as the embodiment shown in FIG. 11. Certainly, the embodiments shown in FIGS. 8, 9 and 10 are also adaptable for this embodiment.

Reference is made to FIG. 13, the present application also provides an electronic equipment 100 including the electronic assembly 1 as provided in the above-described embodiments of the present application.

According to the electronic equipment 100 provided by the present application, by adopting the electronic assembly 1 provided by the above-described embodiments of the present application, the connection performance between the electronic element 30 and the stretchable conductor layer 20 in the electronic equipment 100 can be improved, and the conductivity of the electronic element 30 can be improved.

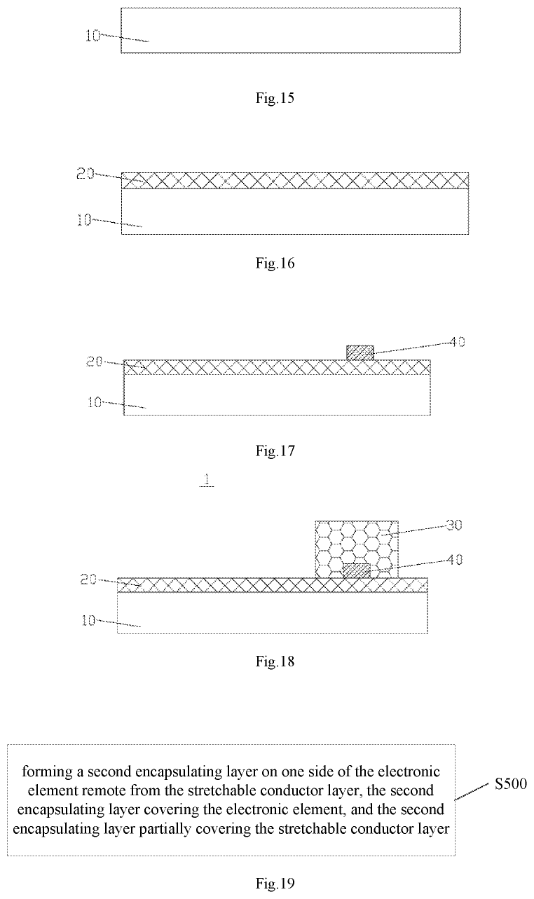

Reference is also made to FIGS. 14-18. FIG. 14 is a process flow diagram of a method for preparing an electronic assembly provided by an embodiment of the present application. FIGS. 15 to 18 are structural schematic diagrams corresponding to S100, S200, S300 and S400 in FIG. 14, respectively. The embodiment provides a method for preparing an electronic assembly 1, the method for preparing the electronic assembly 1 includes S100, S200, S300 and S400. Among them, the detailed description of S100, S200, S300 and S400 is as follows.

Referring to FIG. 15, in S100 an elastic substrate 10 is provided.

Referring to FIG. 16, in S200 a stretchable conductor layer 20 covering the elastic substrate 10 is formed.

Referring to FIG. 17, in S300 a compressible elastic conductor 40 is formed on the surface of the stretchable conductor layer 20 facing away from the elastic substrate 10.

Referring to FIG. 18, in S400 an electronic element 30 electrically connected to the stretchable conductor layer 20 is formed on one side of the stretchable conductor layer 20 facing away from the elastic substrate 10 such that the compressible elastic conductor 40 is at least partially located between the stretchable conductor layer 20 and the electronic element 30.

According to the method for preparing an electronic assembly provided by the present application, a compressible elastic conductor 40 is additionally arranged between the stretchable conductor layer 20 and the electronic element 30 such that the connection performance between the electronic element 30 and the stretchable conductor layer 20 is improved by utilizing the compression-resilience characteristic of the compressible elastic conductor 40, thereby improving the conductivity of the electronic element 30.

Alternatively, the compressible elastic conductor 40 has a compression-resilience characteristic, the compressible elastic conductor 40 including at least one of an elastic conductive micro-spring structural body and an elastic conductive foaming body.

As can be seen from the foregoing, the present application provides a variety of electronic assembly 1 structures. In the following, the method for preparing each electronic assembly 1 is correspondingly described herein.

Reference is also made to FIG. 19 and FIG. 2. FIG. 19 is a partial process flow diagram of a method for preparing an electronic assembly provided by another embodiment of the present application. In this embodiment, the method for preparing the electronic assembly 1B further includes S500. Among them, the detailed description of S500 is as follows.

Referring to FIG. 2, in S500 a second encapsulating layer 60 is formed on one side of the electronic element 30 remote from the stretchable conductor layer 20, the second encapsulating layer 60 covers the electronic element 30, and the second encapsulating layer 60 partially covers the stretchable conductor layer 20.

According to the present application, a second encapsulating layer 60 can be additionally arranged on one side of the electronic element 30 remote from the stretchable conductor layer 20, so that the second encapsulating layer 60 is connected with the stretchable conductor layer 20, the second encapsulating layer 60 covers the electronic element 30, and the second encapsulating layer 60 partially covers the stretchable conductor layer 20. According to the present application, the second encapsulating layer 60 can be used for enabling the resilient force generated by the compressible elastic conductor 40 to be given to the electronic element 30 and enabling the electronic element 30 to be subjected to a force towards the direction of the stretchable conductor layer 20, such that the electronic element 30 is more closely connected with the stretchable conductor layer 20 when the elastic substrate 10 is stretched, and the conductivity performance of the electronic element 30 is further improved. Alternatively, the electronic assembly 1 further includes a second encapsulating layer 60, which is subsequently illustrated herein.

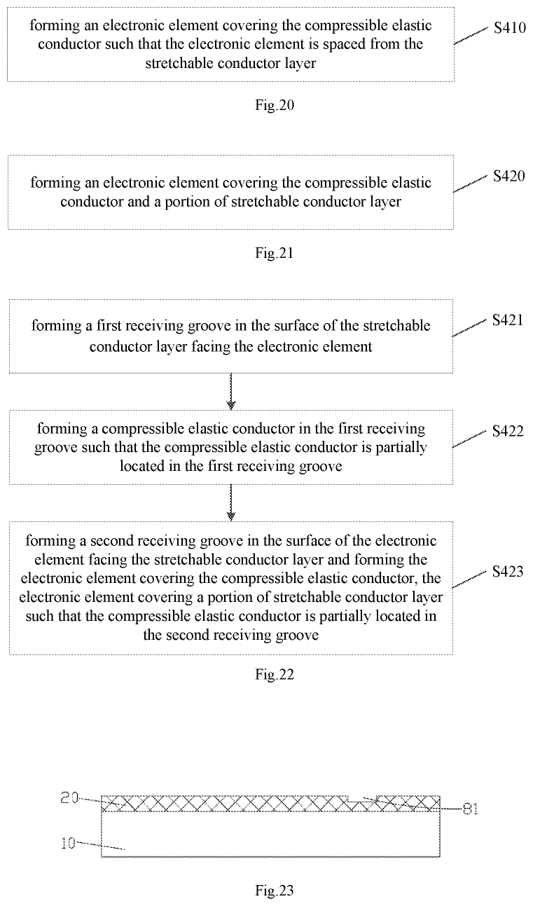

Reference is also made to FIG. 20 and FIG. 3. FIG. 20 is a partial process flow diagram of a method for preparing an electronic assembly provided by yet another embodiment of the present application. In this embodiment, S400 where “an electronic element 30 electrically connected to the stretchable conductor layer 20 is formed on one side of the stretchable conductor layer 20 facing away from the elastic substrate 10 such that the compressible elastic conductor 40 is at least partially located between the stretchable conductor layer 20 and the electronic element 30.” includes S410. Among them, the detailed description of S410 is as follows.

Referring to FIG. 3, in S410 an electronic element 30 covering the compressible elastic conductor 40 is formed such that the electronic element 30 is spaced from the stretchable conductor layer 20.

According to the present application, it is possible to space the electronic element 30 from the stretchable conductor layer 20 by the compressible elastic conductor 40, thereby further improving the size and coverage area of the resilient force and thus further improving the connection performance of the electronic element 30.

Reference is also made to FIG. 21 and FIG. 18. FIG. 21 is a partial process flow diagram of a method for preparing an electronic assembly provided by yet another embodiment of the present application. In this embodiment, S400 where “an electronic element 30 electrically connected to the stretchable conductor layer 20 is formed on one side of the stretchable conductor layer 20 facing away from the elastic substrate 10 such that the compressible elastic conductor 40 is at least partially located between the stretchable conductor layer 20 and the electronic element 30.” includes S420. Among them, the detailed description of S420 is as follows.

Referring to FIG. 18, in S420 an electronic element 30 is formed to cover the compressible elastic conductor 40 and a portion of the stretchable conductor layer 20.

According to the present application, it is also possible that the compressible elastic conductor 40 is arranged on the surface of the stretchable conductor layer 20 facing away from the elastic substrate 10, with the electronic element 30 covering the compressible elastic conductor 40 and a portion of stretchable conductor layer 20. It can also be understood that the compressible elastic conductor 40 is embedded into the electronic element 30.

Reference is also made to FIG. 22-FIG. 25. FIG. 22 is a partial process flow diagram of a method for preparing an electronic assembly provided by yet another embodiment of the present application. FIGS. 23 to 25 are structural schematic diagrams corresponding to S421, S422 and S423 in FIG. 22, respectively. In this embodiment, after S420 “forming the stretchable conductor layer 20 covering the elastic substrate 10”, the method for preparing the electronic assembly 1D further includes S421, S422 and S423. Among them, the detailed description of S421, S422 and S423 is as follows.

Referring to FIG. 23, in S421 a first receiving groove 81 is formed in the surface of the stretchable conductor layer 20 facing the electronic element 30.

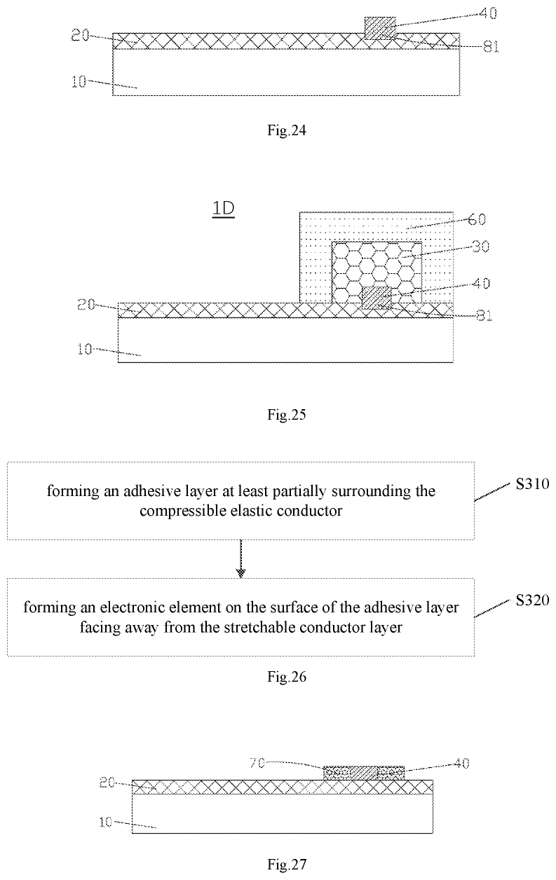

Referring to FIG. 24, in S422 a compressible elastic conductor 40 is formed in the first receiving groove 81 such that the compressible elastic conductor 40 is partially located in the first receiving groove 81.

Referring to FIG. 25, in S423, a second receiving groove 82 is formed in the surface of the electronic element 30 facing the stretchable conductor layer 20 and the electronic element 30 covering the compressible elastic conductor 40 is formed, the electronic element 30 covers a portion of the stretchable conductor layer 20 such that the compressible elastic conductor 40 is partially located in the second receiving groove 82.

According to the present application, it is also possible that the first receiving groove 81 is formed in the surface of the stretchable conductor layer 20 facing the electronic element 30, a second receiving groove 82 is formed in the surface of the electronic element 30 facing the stretchable conductor layer 20, the first receiving groove 81 and the second receiving groove 82 are arranged opposite to each other, and a portion of the compressible elastic conductor 40 is arranged in the first receiving groove 81 and a portion of the compressible elastic conductor 40 is arranged in the second receiving groove 82. It will also be understood as that a portion of the compressible elastic conductor 40 is embedded in the stretchable conductor layer 20 and a portion of the compressible elastic conductor 40 is embedded in the electronic element 30, thereby increasing the height of the compressible elastic conductor 40 and increasing its resiliency, and thus thereby improving the connection performance between the electronic element 30 and the stretchable conductor layer 20.

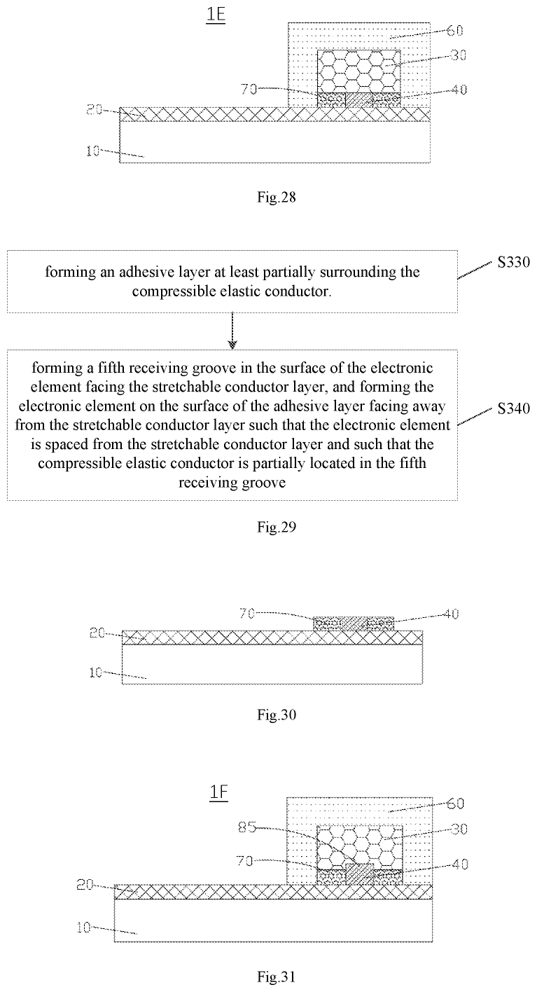

Reference is also made to FIGS. 26-28. FIG. 26 is a partial process flow diagram of a method for preparing an electronic assembly provided by yet another embodiment of the present application. FIGS. 27-28 are structural schematic diagrams corresponding to S310 and S320 in FIG. 26, respectively. In this embodiment, before S400″ forming an electronic element 30 electrically connected to the stretchable conductor layer 20 on one side of the stretchable conductor layer 20 facing away from the elastic substrate 10″, the method for preparing the electronic assembly 1E further includes S310 and S320. Among them, the detailed description of S310 and S320 is as follows.

Referring to FIG. 27, in S310 an adhesive layer 70 is formed at least partially surrounding the compressible elastic conductor 40.

Referring to FIG. 28, in S320 an electronic element 30 is formed on the surface of the adhesive layer 70 facing away from the stretchable conductor layer 20.

According to the present application, the adhesive layer 70 can be arranged on the periphery of the compressible elastic conductor 40 so as to improve the connection performance of the compressible elastic conductor 40, and the adhesive layer 70 can be used for improving the connection performance of the stretchable conductor layer 20 and the electronic element 30 so as to further improve the stability of the electronic assembly 1E.

Reference is also made to FIGS. 29-31. FIG. 29 is a partial process flow diagram of a method for preparing an electronic assembly provided by yet another embodiment of the present application. FIGS. 30 to 31 are structural schematic diagrams corresponding to S330 and S340 in FIG. 29, respectively. In this embodiment, before S400 “forming an electronic element 30 electrically connected to the stretchable conductor layer 20 on one side of the stretchable conductor layer 20 facing away from the elastic substrate 10”, the method for preparing the electronic assembly 1F further includes S330 and S340. Among them, the detailed description of S330 and S340 is as follows.

Referring to FIG. 30, in S330 an adhesive layer 70 is formed at least partially surrounding the compressible elastic conductor 40.

Referring to FIG. 31, in S340 a fifth receiving groove 85 is formed in the surface of the electronic element 30 facing the stretchable conductor layer 20, and the electronic element 30 is formed on the surface of the adhesive layer 70 facing away from the stretchable conductor layer 20 such that the electronic element 30 is spaced from the stretchable conductor layer 20 and such that the compressible elastic conductor 40 is partially located in the fifth receiving groove 85.

According to the present application, the adhesive layer 70 can be arranged on the periphery of the compressible elastic conductor 40 so as to improve the connection performance of the compressible elastic conductor 40, and the adhesive layer 70 can be used for improving the connection performance of the stretchable conductor layer 20 and the electronic element 30 so as to further improve the stability of the electronic assembly 1F. In addition, according to the present application, a portion of the compressible elastic conductor 40 can be arranged in the fifth receiving groove 85 formed in the surface of the electronic element 30, thereby improving the height of the compressible elastic conductor 40 and the resilience thereof, and thus improving the connection performance between the electronic element 30 and the stretchable conductor layer 20.

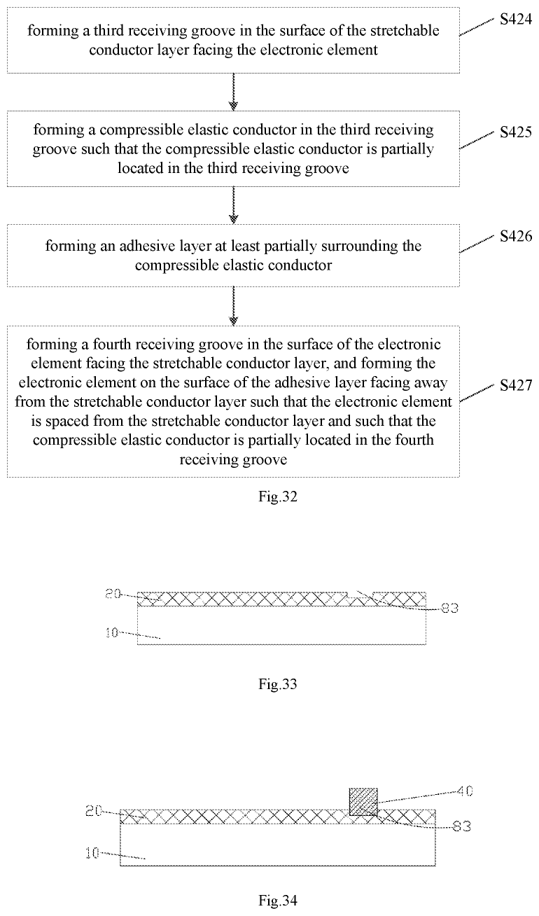

Reference is also made to FIGS. 32-36. FIG. 32 is a partial process flow diagram of a method for preparing an electronic assembly provided by yet another embodiment of the present application. FIGS. 33-36 are structural schematic diagrams corresponding to S424, S425, S426 and S427 in FIG. 32, respectively. In this embodiment, after S420 “forming the stretchable conductor layer 20 covering the elastic substrate 10”, the method for preparing the electronic assembly 1G further includes S424, S425, S426 and S427. Among them, the detailed description of S424, S425, S426 and S427 is as follows.

Referring to FIG. 33, in S424 a third receiving groove 83 is formed in the surface of the stretchable conductor layer 20 facing the electronic element 30.

Referring to FIG. 34, in S425 a compressible elastic conductor 40 is formed in the third receiving groove 83 such that the compressible elastic conductor 40 is partially located in the third receiving groove 83;

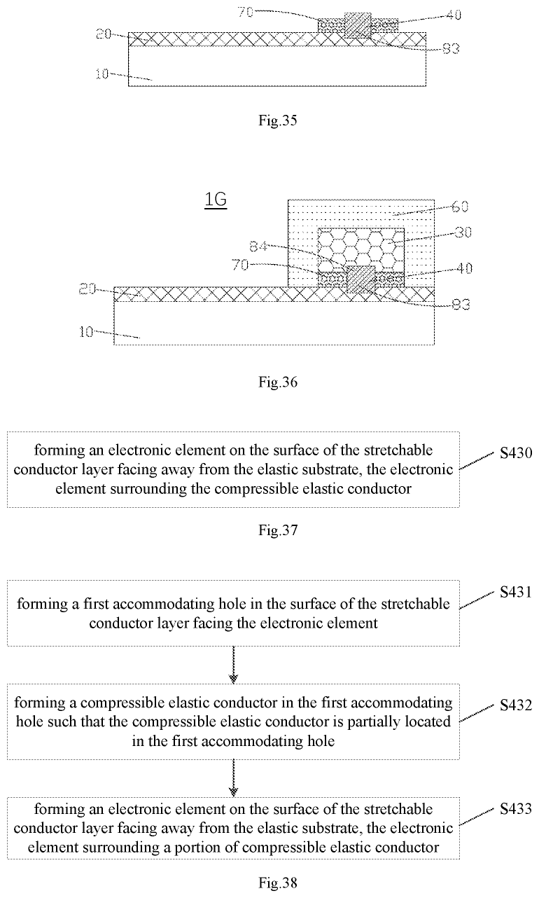

referring to FIG. 35, in S426 an adhesive layer 70 is formed at least partially surrounding the compressible elastic conductor 40.

Referring to FIG. 36, in S427 a fourth receiving groove 84 is formed in the surface of the electronic element 30 facing the stretchable conductor layer 20, and the electronic element 30 is formed on the surface of the adhesive layer 70 facing away from the stretchable conductor layer 20 such that the electronic element 30 is spaced from the stretchable conductor layer 20 and such that the compressible elastic conductor 40 is partially located in the fourth receiving groove 84.

According to the present application, the adhesive layer 70 can be arranged on the periphery of the compressible elastic conductor 40 so as to improve the connection performance of the compressible elastic conductor 40, and the adhesive layer 70 can be used for improving the connection performance of the stretchable conductor layer 20 and the electronic element 30 so as to further improve the stability of the electronic assembly 1G. In addition, according to the present application, a portion of the compressible elastic conductor 40 can be arranged in the third receiving groove 83 formed in the surface of the stretchable conductor layer 20, and a portion of thecompressible elastic conductor 40 can be arranged in the fourth receiving groove 84 formed in the surface of the electronic element 30, thereby further improving the height of the compressible elastic conductor 40 and the resilience thereof, and thus improving the connection performance between the electronic element 30 and the stretchable conductor layer 20.

Reference is also made to FIG. 37 and FIG. 8. FIG. 37 is a partial process flow diagram of a method for preparing an electronic assembly provided by yet another embodiment of the present application. In this embodiment, S400 where “an electronic element 30 electrically connected to the stretchable conductor layer 20 is formed on one side of the stretchable conductor layer 20 facing away from the elastic substrate 10 such that the compressible elastic conductor 40 at least partially is located between the stretchable conductor layer 20 and the electronic element 30.” includes S430. Among them, the detailed description of S430 is as follows.

Referring to FIG. 8, in S430 an electronic element 30 is formed on the surface of the stretchable conductor layer 20 facing away from the elastic substrate 10, the electronic element 30 surrounding the compressible elastic conductor 40.

This embodiment can also be understood as providing a through-hole in the electronic element 30, and forming the electronic element 30 on the surface of the stretchable conductor layer 20 facing away from the elastic substrate 10 such that the compressible elastic conductor 40 is located in the through-hole. The present application may also arrange a through-hole in the electronic element 30 and arrange the compressible elastic conductor 40 in the through-hole. This not only further increases the height of the compressible elastic conductor 40, thereby increasing its resiliency. The resilient force of the compressible elastic conductor 40 may also act directly on the second encapsulating layer 60, thereby increasing the force imparted to the electronic element 30 by the second encapsulating layer 60 and increasing the utilization of the resilient force.

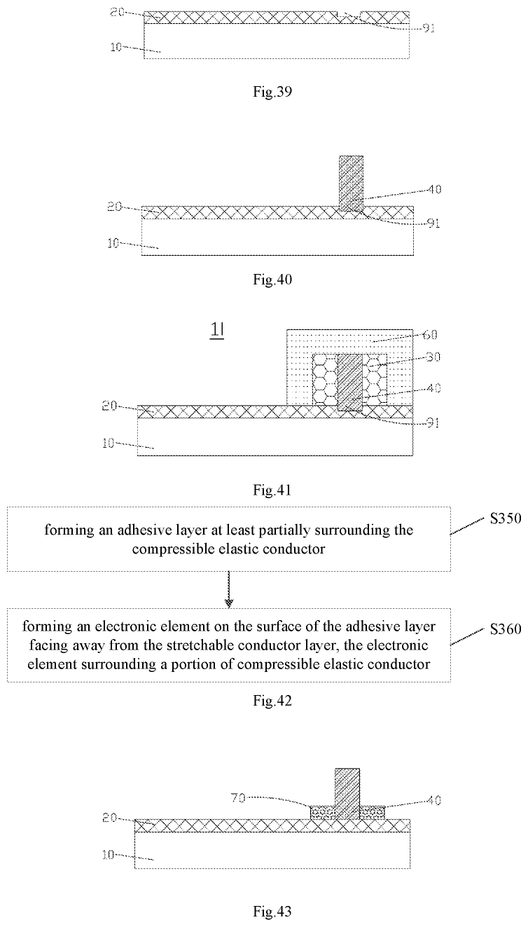

Reference is also made to FIGS. 38-41. FIG. 38 is a partial process flow diagram of a method for preparing an electronic assembly provided by yet another embodiment of the present application. FIGS. 39-41 are structural schematic diagrams corresponding to S431, S432 and S433 in FIG. 38, respectively. In this embodiment, after S420 “forming the stretchable conductor layer 20 covering the elastic substrate 10”, the method for preparing the electronic assembly 1I further includes S431, S432 and S433. Among them, the detailed description of S431, S432 and S433 is as follows.

Referring to FIG. 39, in S431 a first accommodating hole 91 is formed in the surface of the stretchable conductor layer 20 facing the electronic element 30.

Referring to FIG. 40, in S432 a compressible elastic conductor 40 is formed in the first accommodating hole 91 such that the compressible elastic conductor 40 is partially located in the first accommodating hole 91.

Referring to FIG. 41, in S433 an electronic element 30 is formed on the surface of the stretchable conductor layer 20 facing away from the elastic substrate 10, the electronic element 30 surrounding a portion of thecompressible elastic conductor 40.

First, the present application may also arrange a through-hole in the electronic element 30 and arrange the compressible elastic conductor 40 in the through-hole. This not only further increases the height of the compressible elastic conductor 40, thereby increasing its resiliency. The resilient force of the compressible elastic conductor 40 may also act directly on the second encapsulating layer 60, thereby increasing the force imparted to the electronic element 30 by the second encapsulating layer 60 and increasing the utilization of the resilient force. Secondly, according to the present application, a portion of the compressible elastic conductor 40 can be arranged in the first accommodating hole 91 formed in the stretchable conductor layer 20, such that the height of the compressible elastic conductor 40 is further improved, the resilient force of the compressible elastic conductor 40 is improved, and the connection performance between the electronic element 30 and the stretchable conductor layer 20 is further improved.

Reference is also made to FIGS. 42-44. FIG. 42 is a partial process flow diagram of a method for preparing an electronic assembly provided by yet another embodiment of the present application. FIGS. 43-44 are structural schematic diagrams corresponding to S350 and S360 in FIG. 42, respectively. In this embodiment, before S400 where “an electronic element 30 electrically connected to the stretchable conductor layer 20 is formed on one side of the stretchable conductor layer 20 facing away from the elastic substrate 10 such that the compressible elastic conductor 40 is at least partially located between the stretchable conductor layer 20 and the electronic element 30.”, the method for preparing the electronic assembly 1J further includes S350 and S360. Among them, the detailed description of S350 and S360 is as follows.

Referring to FIG. 43, in S350 an adhesive layer 70 is formed at least partially surrounding the compressible elastic conductor 40.

Referring to FIG. 44, in S360 an electronic element 30 is formed on the surface of the adhesive layer 70 facing away from the stretchable conductor layer 20, the electronic element 30 surrounding a portion of the compressible elastic conductor 40.

First, the present application may also arrange a through-hole in the electronic element 30 and arrange the compressible elastic conductor 40 in the through-hole. This not only further increases the height of the compressible elastic conductor 40, thereby increasing its resiliency. The resilient force of the compressible elastic conductor 40 may also act directly on the second encapsulating layer 60, thereby increasing the force imparted to the electronic element 30 by the second encapsulating layer 60 and increasing the utilization of the resilient force. Secondly, the present application may further dispose the adhesive layer 70 on the periphery of the compressible elastic conductor 40 to improve the connection performance of the compressible elastic conductor 40, and may further improve the connection performance of the stretchable conductor layer 20 with the electronic element 30 by using the adhesive layer 70 to further improve the stability of the electronic assembly 1J.

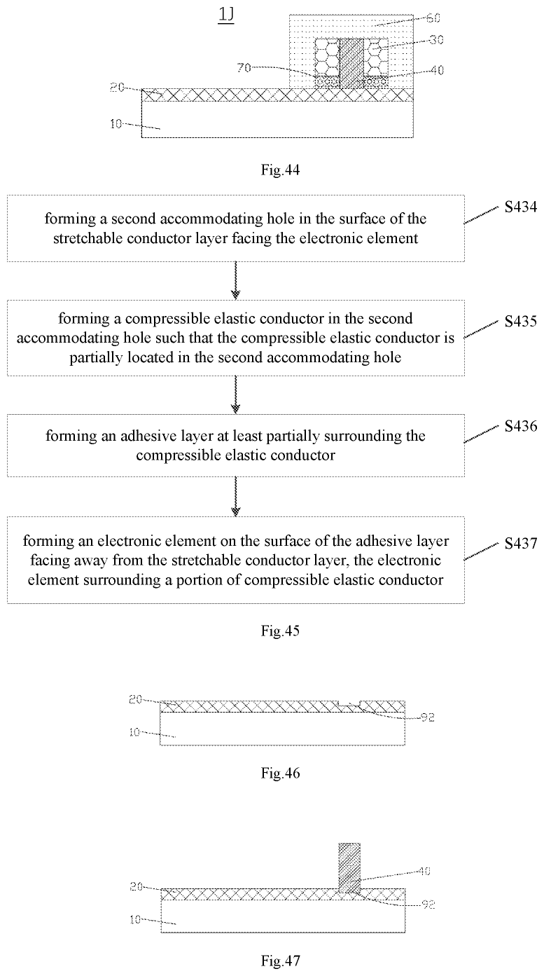

Reference is also made to FIGS. 45-49. FIG. 45 is a partial process flow diagram of a method for preparing an electronic assembly provided by yet another embodiment of the present application. FIGS. 46 to 49 are structural schematic diagrams corresponding to S434, S435, S436 and S437 in FIG. 45, respectively. In this embodiment, after S420 “forming the stretchable conductor layer 20 covering the elastic substrate 10”, the method for preparing the electronic assembly 1K further includes S434, S435, S436 and S437. Among them, the detailed description of S434, S435, S436 and S437 is as follows.

Referring to FIG. 46, in S434 a second accommodating hole 92 is formed in the surface of the stretchable conductor layer 20 facing the electronic element 30.

Referring to FIG. 47, in S435 a compressible elastic conductor 40 is formed in the second accommodating hole 92 such that the compressible elastic conductor 40 is partially located in the second accommodating hole 92.

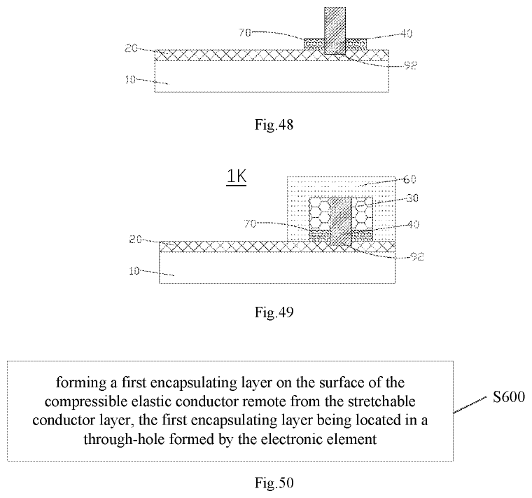

Referring to FIG. 48, in S436 an adhesive layer 70 is formed at least partially surrounding the compressible elastic conductor 40.

Referring to FIG. 49, in S437 an electronic element 30 is formed on the surface of the adhesive layer 70 facing away from the stretchable conductor layer 20, the electronic element 30 surrounding a portion of thecompressible elastic conductor 40.

First, the present application may also arrange a through-hole in the electronic element 30 and arrange the compressible elastic conductor 40 in the through-hole. This not only further increases the height of the compressible elastic conductor 40, thereby increasing its resiliency. The resilient force of the compressible elastic conductor 40 may also act directly on the second encapsulating layer 60, thereby increasing the force imparted to the electronic element 30 by the second encapsulating layer 60 and increasing the utilization of the resilient force. Secondly, the present application may further arrange the adhesive layer 70 on the periphery of the compressible elastic conductor 40 to improve the connection performance of the compressible elastic conductor 40, and may further improve the connection performance of the stretchable conductor layer 20 with the electronic element 30 by using the adhesive layer 70 to further improve the stability of the electronic assembly 1K. Thirdly, according to the present application, a portion of the compressible elastic conductor 40 can be arranged in a second accommodating hole 92 formed in the stretchable conductor layer 20, such that the height of the compressible elastic conductor 40 is further improved, the resilient force of the compressible elastic conductor 40 is improved, and the connection performance between the electronic element 30 and the stretchable conductor layer 20 is further improved.

Reference is also made to FIG. 50 and FIG. 12. FIG. 50 is a partial process flow diagram of a method for preparing an electronic assembly provided by yet another embodiment of the present application. The method for preparing the electronic assembly 1L further includes S600. Among them, the detailed description of S600 is as follows.

Referring to FIG. 12, in S600, a first encapsulating layer 50 is formed on the surface of the compressible elastic conductor 40 remote from the stretchable conductor layer 20, the first encapsulating layer 50 being located in a through-hole formed by the electronic element 30.

First, the present application may also arrange a through-hole in the electronic element 30 and arrange the compressible elastic conductor 40 in the through-hole. This not only further increases the height of the compressible elastic conductor 40, thereby increasing its resiliency. The resilient force of the compressible elastic conductor 40 may also act directly on the second encapsulating layer 60, thereby increasing the force imparted to the electronic element 30 by the second encapsulating layer 60 and increasing the utilization of the resilient force. Secondly, the present application may further arrange a first encapsulating layer 50 on the surface of the compressible elastic conductor 40 remote from the stretchable conductor layer 20, with one side of the first encapsulating layer 50 connected to the compressible elastic conductor 40, and the other side of the first encapsulating layer 50 connected to the second encapsulating layer to better fix the compressible elastic conductor 40. Alternatively, the first encapsulating layer 50 includes a glue layer or a conductive glue layer or a mechanical member and the like.

Alternatively, for the sequential formation of the electronic element 30 and the compressible elastic conductor 40, in an embodiment of the present application, the electronic element 30 may be formed on one side of the stretchable conductor layer 20 facing away from the elastic substrate 10, and then the compressible elastic conductor 40 may be formed in the through-hole provided in the electronic element 30.

Alternatively, in another embodiment of the present application, the compressible elastic conductor 40 may be formed on one side of the stretchable conductor layer 20 facing away from the elastic substrate 10, and then the electronic element 30 surrounding the compressible elastic conductor 40 may be formed on the peripheral side of the compressible elastic conductor 40.

The above provides a detailed introduction to the content provided by the embodiments of the present application. The present application explains and illustrates the principles and embodiments of the present application. The above description is only used to help understand the methods and core ideas of the present application; at the same time, for those of ordinary skills in the art, according to the idea of the present application, there will be changes in the specific embodiments and the scope of application. In summary, the content of this description should not be construed as a limitation of the present application.

What is claimed is:

1. An electronic assembly, comprising an elastic substrate, a stretchable conductor layer, an electronic element and a compressible elastic conductor, wherein the stretchable conductor layer is arranged on the elastic substrate, the electronic element is located on one side of the stretchable conductor layer facing away from the elastic substrate, the stretchable conductor layer is electrically connected to the electronic element, and the compressible elastic conductor is at least partially located between the stretchable conductor layer and the electronic element.

2. The electronic assembly of claim 1, wherein the compressible elastic conductor has a compression-resilience characteristic, the compressible elastic conductor comprising at least one of an elastic conductive micro-spring structural body and an elastic conductive foaming body.

3. The electronic assembly of claim 1, wherein the compressible elastic conductor is located on a surface of the stretchable conductor layer facing away from the elastic substrate, the electronic element is located on a surface of the compressible elastic conductor facing away from the stretchable conductor layer, and the electronic element is spaced from the stretchable conductor layer.

4. The electronic assembly of claim 1, wherein the compressible elastic conductor is located on a surface of the stretchable conductor layer facing away from the elastic substrate, and the electronic element covers the compressible elastic conductor and a portion of the stretchable conductor layer.

5. The electronic assembly of claim 1, wherein a surface of the stretchable conductor layer facing the electronic element has a first receiving groove, a surface of the electronic element facing the stretchable conductor layer has a second receiving groove, the compressible elastic conductor is partially located in the first receiving groove, the compressible elastic conductor is partially located in the second receiving groove, and the electronic element covers a portion of the stretchable conductor layer.

6. The electronic assembly of claim 1, wherein the compressible elastic conductor is located on a surface of the stretchable conductor layer facing away from the elastic substrate, the electronic element is located on a surface of the compressible elastic conductor facing away from the stretchable conductor layer, an adhesive layer is arranged between the electronic element and the stretchable conductor layer, and the adhesive layer i arranged at least partially around the compressible elastic conductor.

7. The electronic assembly of claim 1, wherein a surface of the stretchable conductor layer facing the electronic element has a third receiving groove, a surface of the electronic element facing the stretchable conductor layer has a fourth receiving groove, the compressible elastic conductor is partially located in the third receiving groove, the compressible elastic conductor is partially located in the fourth receiving groove, an adhesive layer is arranged between the electronic element and the stretchable conductor layer, and the adhesive layer is arranged at least partially around the compressible elastic conductor.

8. The electronic assembly of claim 1, wherein a surface of the electronic element facing the stretchable conductor layer has a fifth receiving groove, the compressible elastic conductor is partially located in the fifth receiving groove, an adhesive layer is arranged between the electronic element and the stretchable conductor layer, and the adhesive layer is arranged at least partially around the compressible elastic conductor.

9. The electronic assembly of claim 1, wherein the electronic element is located on a surface of the stretchable conductor layer, the electronic element has a through-hole, and the compressible elastic conductor is located in the through-hole.

10. The electronic assembly of claim 1, wherein the electronic element has a through-hole, a surface of the stretchable conductor layer facing the electronic element has a first accommodating hole, the compressible elastic conductor is partially located in the through-hole, and the compressible elastic conductor is partially located in the first accommodating hole.

11. The electronic assembly of claim 1, wherein the electronic element is spaced from the stretchable conductor layer, the electronic element has a through-hole in which the compressible elastic conductor is partially located, an adhesive layer is arranged between the electronic element and the stretchable conductor layer, and the adhesive layer at least partially surrounds the compressible elastic conductor.

12. The electronic assembly of claim 1, wherein the electronic element is spaced from the stretchable conductor layer, the electronic element has a through-hole, a surface of the stretchable conductor layer facing the electronic element has a second accommodating hole, the compressible elastic conductor is partially located in the through-hole, the compressible elastic conductor is partially located in the second accommodating hole, an adhesive layer is arranged between the electronic element and the stretchable conductor layer, and the adhesive layer at least partially surrounds the compressible elastic conductor.

13. The electronic assembly of claim 1, further comprising a second encapsulating layer located on one side of the electronic element remote from the stretchable conductor layer, the second encapsulating layer covering the electronic element, and the second encapsulating layer partially covering the stretchable conductor layer.

14. The electronic assembly of claim 13, further comprising a first encapsulating layer, wherein the electronic element has a through-hole, the compressible elastic conductor is at least partially located in the through-hole, the first encapsulating layer is located in the through-hole and the first encapsulating layer is located on a surface of the compressible elastic conductor remote from the stretchable conductor layer, one side of the first encapsulating layer is connected to the compressible elastic conductor, and the other side of the first encapsulating layer is connected to the second encapsulating layer.

15. An electronic equipment, comprising an electronic assembly, wherein the electronic assembly comprises an elastic substrate, a stretchable conductor layer, an electronic element and a compressible elastic conductor, the stretchable conductor layer is arranged on the elastic substrate, the electronic element is located on one side of the stretchable conductor layer facing away from the elastic substrate, the stretchable conductor layer is electrically connected to the electronic element, and the compressible elastic conductor is at least partially located between the stretchable conductor layer and the electronic element.

16. The electronic equipment of claim 15, wherein the compressible elastic conductor has a compression-resilience characteristic, the compressible elastic conductor comprising at least one of an elastic conductive micro-spring structural body and an elastic conductive foaming body.

17. The electronic equipment of claim 15, wherein the electronic assembly further comprises a second encapsulating layer located on one side of the electronic element remote from the stretchable conductor layer, the second encapsulating layer covering the electronic element, and the second encapsulating layer partially covering the stretchable conductor layer.

18. A method for preparing an electronic assembly, comprising:
providing an elastic substrate;
forming a stretchable conductor layer covering the elastic substrate;
forming a compressible elastic conductor on a surface of the stretchable conductor layer facing away from the elastic substrate; and
forming an electronic element electrically connected to the stretchable conductor layer on one side of the stretchable conductor layer facing away from the elastic substrate such that the compressible elastic conductor is located at least partially between the stretchable conductor layer and the electronic element.

19. The method for preparing an electronic assembly of claim 18, further comprising:
forming a second encapsulating layer on one side of the electronic element remote from the stretchable conductor layer, wherein the second encapsulating layer covers the electronic element, and the second encapsulating layer partially covers the stretchable conductor layer.

20. The method for preparing an electronic assembly of claim 19, further comprising:
forming a first encapsulating layer on a surface of the compressible elastic conductor remote from the stretchable conductor layer, wherein the compressible elastic conductor is at least partially located in the through-hole, and the first encapsulating layer is located in the through-hole, one side of the first encapsulating layer is connected to the compressible elastic conductor, and the other side of the first encapsulating layer is connected to the second encapsulating layer.
